(19) United States
(12) Patent Application Publication
(10) Pub. No.: US 2025/0253143 A1
(43) Pub. Date: Aug. 7, 2025

(54) Method and Apparatus for Cleaning a Wafer Edge and Bevel

(71) Applicant: Product Systems Incorporated, Campbell, CA (US)

(72) Inventors: Mark J. Beck, Los Gatos, CA (US); Eric G. Liebscher, San Jose, CA (US)

(73) Assignee: Product Systems Incorporated, Campbell, CA (US)

(21) Appl. No.: 19/042,503

(22) Filed: Jan. 31, 2025

Related U.S. Application Data
(60) Provisional application No. 63/548,801, filed on Feb. 1, 2024.

(51) Int. Cl. H01L 21/02; H01L 21/67

(52) U.S. Cl. CPC H01L 21/02087; H01L 21/6704

(57) ABSTRACT

A method and tool for cleaning the edge exclusion region of a semiconductor wafer, including the bevel regions. The tool comprises a crystal for generating acoustic energy, a resonator for propagating the acoustic energy away from the resonator, and a cleaning zone where the substrate is cleaned. The resonator is shaped to focus the acoustic energy on a focal point located in the cleaning zone. The method comprises causing a circular substrate to be rotated, positioning a crystal and shaped resonator transducer near the substrate, causing a volume of cleaning fluid to contact at least part of the substrate, generating acoustic energy by applying power to the crystal, focusing the acoustic energy by transmitting the acoustic energy through the resonator, and transmitting the focused acoustic energy into at least some of the volume of cleaning fluid that is in contact with the substrate.

### RELATED APPLICATIONS

This application claims the benefit of U.S. provisional application 63/548,801, filed Feb. 1, 2024, which is incorporated herein by reference.

### TECHNICAL FIELD

This invention relates to a wafer cleaning apparatus and method, and more particularly to a system that uses focused acoustic energy and liquid to clean particles from the edge exclusion region of a semiconductor wafer.

### BACKGROUND OF THE INVENTION

Integrated circuits (IC's) are an essential part of our economy. Manufacturing an advanced IC can take as many as a thousand processing steps over a fifteen-week period and may require as many as five hundred different tools. The manufacturing process is performed in special clean rooms and uses very clean water and chemicals. Over 40% of the steps to make an IC are called “cleans” where undesirable residues called “particulate contamination” left on the substrate/wafer during various processing steps are removed. If the particulate contamination is not removed, the particles can dislodge and contaminate the processing during later steps.

Semiconductor dies (ICs) are usually made on a circular substrate (i.e., a wafer), but rectangular dies cannot be made all the way to the edge of a circular/round substrate. Therefore, the substrate has an “edge exclusion” region around the circumference. Some of the tools used during the cleaning steps are not made to clean this edge exclusion region, and this can result in contaminants being left on the edge and bevel of the substrate on the front and backside of the substrate.

FIG. 1 illustrates the “edge exclusion” region 10 of a representative semiconductor wafer (substrate) 14, such as a 300 mm wafer. The wafer 14 has a top side 18, a bottom side 22, an upper bevel 26, a bottom bevel 30, and an apex 34. Sometimes the bevels and apex can be more rounded than is illustrated in FIG. 1. Generally, the edge exclusion region has a length of approximately three to seven millimeters (3-7 mm). The present invention is a tool and method for cleaning the edge exclusion region 10 on the top and bottom sides of the wafer 14, including the bevels 26 and 30, and the apex 34.

### SUMMARY OF THE INVENTION

Briefly, the present invention comprises a method and tool for cleaning specific areas on a substrate, such as the edge exclusion region of a semiconductor wafer, using focused acoustic energy and cleaning fluid. The tool comprises a crystal for generating acoustic energy, a resonator attached to the crystal for propagating (or conducting) the focused acoustic energy to the cleaning fluid, and a cleaning chamber positioned inside the resonator for accepting the cleaning fluid. The resonator is shaped to focus the acoustic energy on a region a distance away from the resonator. This allows the acoustic energy to be focused on the specific region of the substrate to be cleaned, such as the edge exclusion region of the semiconductor wafer.

The method comprises causing a circular substrate such as a semiconductor wafer to be rotated, positioning a transducer comprised of a crystal and a shaped resonator near at least a part of the substrate, causing a volume of cleaning fluid to contact at least part of the substrate, generating acoustic energy by applying RF power to the crystal, focusing the acoustic energy by transmitting the acoustic energy generated by the crystal through the shaped resonator to produce focused acoustic energy, and transmitting at least some of the focused acoustic energy into at least some of the volume of cleaning fluid that is in contact with the substrate. The edge exclusion region of the wafer is moved horizontally (i.e., laterally) through the region of focused acoustic energy to achieve the desired cleaning.

### BRIEF DESCRIPTION OF THE DRAWINGS

FIG. 1 is a schematic view of the edge exclusion zone of a wafer according to the prior art.

FIG. 2 is a cross-sectional view of an edge cleaning tool according to the present invention.

FIG. 3 is a schematic cross-sectional view of the cleaning chamber and transducer according to the present invention.

FIG. 4 is a schematic view illustrating the focal point of the cylindrical lens according to the present invention.

FIG. 5 is a schematic isometric view of the resonator and crystal according to the present invention.

FIG. 6 is an isometric view of the exterior cleaning chamber according to the present invention.

### DETAILED DESCRIPTION

The present invention comprises an apparatus and method for cleaning a substrate such as the edge exclusion region of a semiconductor wafer. Other substrates can also be cleaned with the apparatus. In the present invention, the edge exclusion region of the wafer is cleaned using a cleaning fluid and acoustic energy that can be focused on or near a part of the edge exclusion region. As mentioned previously, the edge exclusion region is a region that extends around the circumference of a semiconductor wafer where integrated circuits (dies) are not formed and includes the bevel and apex regions of the wafer.

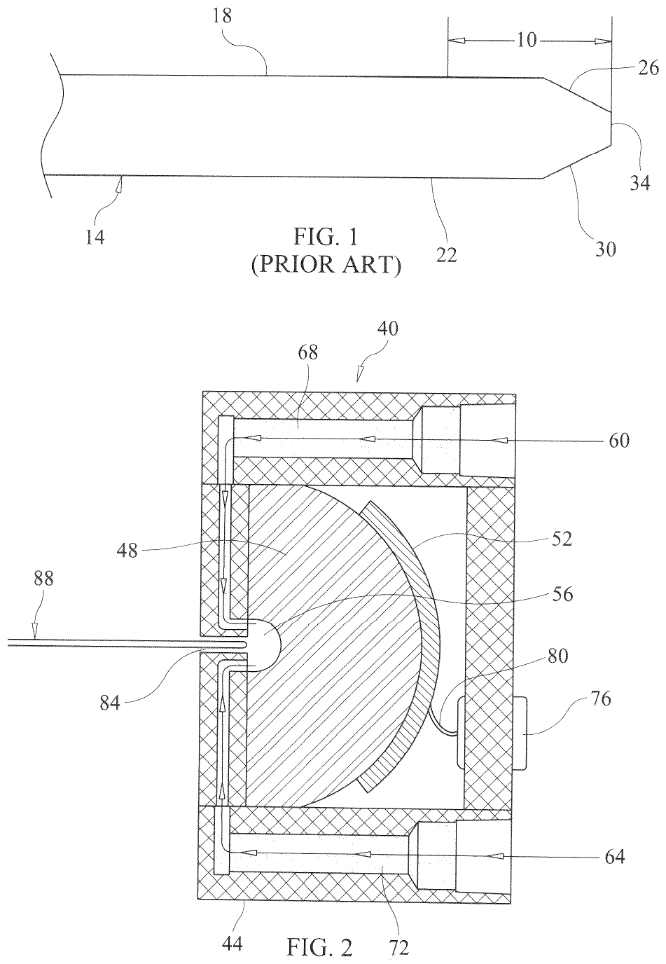

FIG. 2 illustrates a cleaning tool 40 used for cleaning a substrate 88 such as a semiconductor wafer. Preferably, the tool 40 is used to clean the edge exclusion region of a semiconductor wafer, such as edge exclusion region 10 from FIG. 1. In a preferred embodiment, the cleaning tool 40 comprises a housing 44, a resonator 48, a crystal 52, and a cleaning chamber 56 formed in the resonator. Preferably, an upper fluid source 60 and a lower fluid source 64 provide liquid cleaning fluid that will be utilized to clean the edge exclusion region of the wafer, such as by filling the cleaning chamber 56 with the liquid cleaning fluid. However, other designs, such as nozzles or sprayers, can be utilized for supplying liquid cleaning fluid to the wafer and/or cleaning chamber 56. A slot 84 provides access to the cleaning chamber 56 for a substrate 88, such as a semiconductor wafer. The slot 84 is an open space sized to accept a part of the substrate 88 to be cleaned. In a preferred embodiment, liquid cleaning fluid can move from the cleaning chamber 56 into the slot 84 to cover the part of the substrate 88 that is inserted into the slot 84.

The combination of the crystal 52 and the resonator 48 forms a transducer 89. The resonator 48 has a shape that focuses the acoustic energy along a region that will facilitate cleaning of at least part of the substrate 88 such as the edge exclusion region of the wafer. The design of the transducer 89 and the cleaning tool 40 allows the edge exclusion regions on the top side 18 and the wafer surface on the bottom side 22 to be cleaned. Cleaning fluid from the fluid sources 60 and 64 flows through an upper passageway 68 and a lower passageway 72, respectively, and into the cleaning chamber 56. An RF connection 76 and an electrical contact 80 provide an electrical connection to the crystal 52.

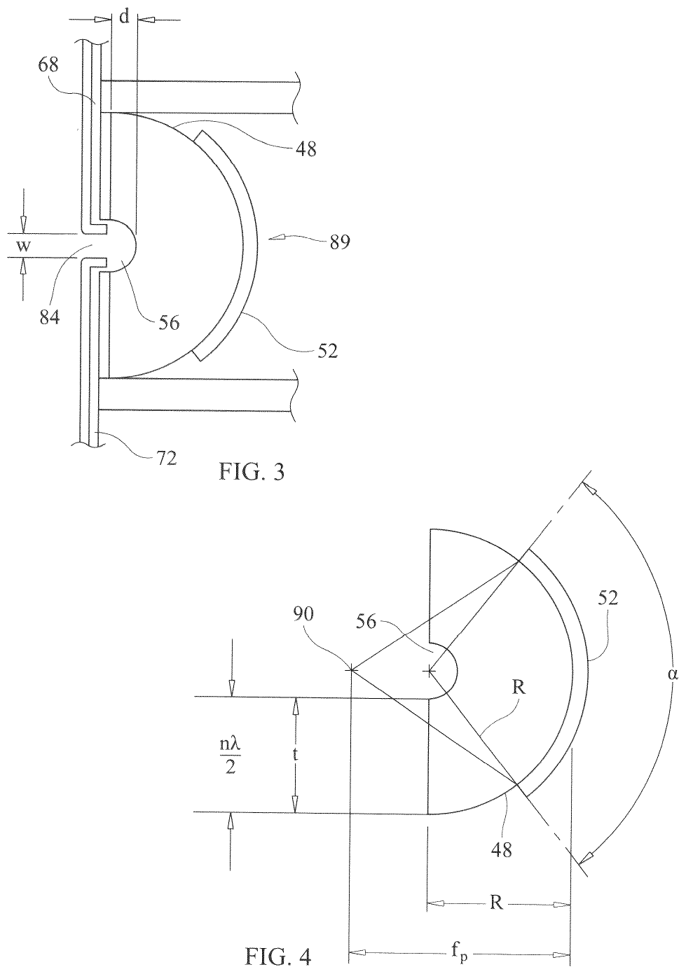

FIG. 3 illustrates the cleaning chamber 56 in more detail. The chamber 56 is a hollow cavity formed in the resonator 48. Preferably, the chamber 56 has a cylindrical shape with a semicircular cross-section, a radius “d,” and a length that is equal to the length “L” of the resonator 48. The chamber 56 abuts the resonator 48 (i.e., interfaces or touches the resonator 48). In a preferred embodiment, the curved outer surface of the chamber 56 (traced by the radius “d”) is completely in contact with the resonator 48.

The slot 84 is an opening in the housing 44 that allows a part of the substrate 88 to be inserted into the slot and optionally, into the cleaning chamber 56, if desired. Cleaning fluid flows into the chamber 56 through the upper passageway 68 and the lower passageway 72. Some of the cleaning fluid flows from the chamber 56 into the slot 84 and covers the surfaces of the substrate 88 that are present in the slot 84, so that the top and bottom sides of the substrate 88 can be cleaned simultaneously. Acoustic energy moving through the resonator 48 is focused so as to enhance cleaning of the substrate 88, such as by being focused inside the slot 84 to enhance cleaning of the edge exclusion region 10 on both the top and bottom sides of the wafer. In other embodiments, one or more additional passageways could be included for draining the cleaning fluid away from the chamber 56.

The slot 84 has a width “w” which is wide enough to allow the substrate 88 (shown in FIG. 2) to be inserted through the slot 84 and into the cleaning chamber 56. The chamber 56 has a depth “d” and the edge exclusion region 10 (shown in FIG. 1) of the substrate 88 can be positioned partially in the slot 84 and partially in the chamber 56 so that various parts of the edge exclusion region can be exposed to the focused acoustic energy for optimal cleaning. In a representative embodiment, “w” is approximately 2 mm and “d” is approximately 7 to 7.5 mm. These dimensions are chosen to accommodate 200- and 300-mm wafers, but other dimensions can be used. Cleaning fluid from the chamber 56 covers the surfaces of the substrate 88 that are present in the slot 84.

Cleaning fluid energized with focused acoustic energy cleans particles from the edge exclusion region 10, including the bevel regions on the top and bottom sides of the substrate 88. Preferably, the part of the wafer containing the edge exclusion region 10 is inserted into the slot 84 and the focal point of the focused acoustic energy will be positioned in the slot 84 so that the part of the edge exclusion region 10 near the focal point receives optimal cleaning. The wafer can be moved horizontally in the slot 84 so that different parts of the edge exclusion region are near the focal point and receive optimal cleaning.

FIG. 4 illustrates how the resonator 48 focuses acoustic energy from the crystal 52 at a focal point 90. Preferably, the transducer 89 is designed so that the focal point 90 is located in the slot 84. The resonator 48 acts like a cylindrical lens to focus the acoustic energy from the crystal 52 at the focal point 90. Here, the term focused acoustic energy means that acoustic energy is caused to converge onto a focal zone (or focal point) thereby increasing the power of the acoustic energy in the focal zone (or focal point) relative to the power generated at the crystal.

Several parameters that affect the design of the transducer 89 are illustrated in FIG. 4. These include the radius R of the resonator 48, the curvature angle “a” of the crystal 52, the thickness “t” of the solid part of the resonator 48 and the position of the focal point 90 shown as fp. Preferably, “t” is selected so that t=nλ/2, where “n” is the ratio of the velocity of sound in the resonator (at Fo—the design frequency of the crystal 52) to the velocity of sound in the cleaning fluid, and λ is the wavelength of sound in resonator 48. Both parameters depend on the material that comprises the resonator 48. Selecting the dimension “t” in this manner optimizes the transmission of acoustic energy through the resonator. Preferably, in the present invention, the focal point 90 is always located at a distance larger than R (i.e., the focal length is larger than the radius R). The radius R is the radius of the cylindrical cross-section of the resonator 48 (considering the resonator as a solid half-cylinder).

The formula for calculating the position of the focal point 90 for the transducer 89 is: fp=R/(n−1)/n, where fp is the focal point 90; R is the radius of the resonator 48; and n is V_{R}/V_{F}, where V_{R} is the velocity of sound in the resonator and V_{F} velocity of sound in the cleaning fluid (both at Fo). The quantity (n−1)/n is sometimes considered to be the acoustic analog of the optical index of refraction. Using this equation, the dimensions and composition of the resonator 48 can be selected so that the focal point 90 is positioned on the edge exclusion region of the wafer 88 when it is inserted in the slot 84 to enhance cleaning of the edge exclusion region 10. Table 1 below gives some values and dimensions for a representative design of the transducer 89.

TABLE 1

| | V_{R} | V_{F} | n | R | λ | | fp (mm) |
|---|---|---|---|---|---|---|---|
| material | (mm/us) | (mm/us) | (=V_{R}/V_{F}) | (mm) | (mm) | (n − 1)/n | (=R/(n − 1)/n) |
| 316 SS | 5.9 | — | 3.9 | 22.5 | 6.37 | .74 | 30 |
| sapphire | 11.1 | — | 7.4 | 22.5 | 12.0 | .86 | 26 |
| water | — | 1.5 | | | 1.62 | | |

Reference to FIG. 4 and Table 1 shows that the focal length (i.e., the distance to fp) is larger than the radius R for both stainless steel and sapphire. Specifically, for stainless steel fp is 30 mm when R is 22.5 mm, and for sapphire, fp is 26 mm when R is 22.5 mm. This means that in a preferred embodiment, fp is located in the slot 84 as opposed to being in the chamber 56. Preferably, the focal point is always located a distance from the resonator 48 meaning that focal length is larger than the radius R.

From the discussion given above, it should be clear that adjusting the dimensions of the components in the cleaning tool 40 will change the focal point, including making the focal point larger or smaller than the focal points listed above. For example, a smaller or larger crystal (or other component change) could vary the focal point a lot, so the present invention is not limited to these ranges.

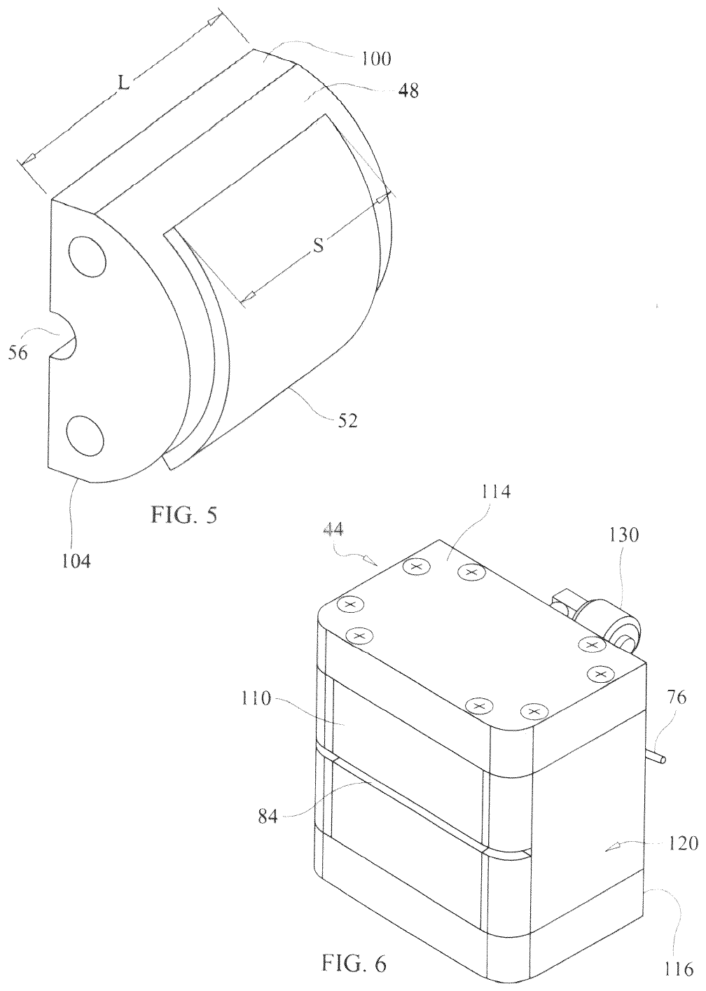

FIG. 5 illustrates that the resonator 48 has the shape of a half-cylinder having the length “L” and an upper flattened section 100 and a lower flattened section 104. The crystal 52 has a length “S” and has a curved shape that fits tightly against an outside surface of the resonator 48. In a preferred embodiment, the length “L” of the resonator 48 is approximately 1.97 inches (50.0 mm) and the length “S” of crystal 52 is approximately 1.58 inches (40.0 mm), but other dimensions can be used. These preferred embodiment dimensions can be used with 300- and 200-mm wafers.

Preferably, the crystal 52 is attached to the resonator 48 using an attachment material such as indium, indium alloys, or an epoxy, but other materials can be used, including natural or synthetic adhesives. In a preferred embodiment, the crystal 52 comprises a ceramic crystal that vibrates at a designed frequency, such as PZT crystal (lead zirconate titanate crystal), but the crystal 52 can be comprised of other materials. Examples of other materials include other piezoelectric ceramic materials, such as materials comprised of barium, titanate, quartz, or zinc, as well as non-ceramic crystals. In a preferred embodiment, the crystal 52 is a 100-degree “a” PZT crystal operating at 925 kHz (i.e., in FIG. 4, the angle alpha would be 100-degrees). In a preferred embodiment, the resonator 48 is comprised of sapphire, but other materials such as stainless steel (e.g. 316 stainless steel), vitreous carbon, quartz, SiN, SiC, tantalum, chromium, nickel, Hastelloy alloy, and diamond-like coated materials can be used. A general consideration for the resonator material is that it is compatible with the cleaning fluid being used (i.e., it doesn't react with the cleaning fluid).

Other design goals for the transducer 89 include knowing where fp is so that the cleaning chamber 56 and slot 84 are designed to allow the part of the substrate to be cleaned to be positioned near fp; selecting appropriate values for Fo, “a,” and R; and designing the resonator 48 to be nλ/2 thick so the acoustic energy is most efficiently transmitted through it to the cleaning fluid.

Reference to FIGS. 5 and 6 illustrates that the slot 84 extends along the length “L” of the resonator 48 parallel to the cleaning chamber 56. Additionally, the focused acoustic energy lies in a focal region that includes the focal point “fp” but has the shape of a cylinder (focal cylinder) that extends along the length “S” of the crystal 52 (and parallel to “S”) inside the slot 84, with the focal point “fp” being at the center of the cylinder. The radius of the cross section of this focal cylinder is given by the equation r=0.18λ/sin a/2, where r is the radius of the cross section and λ and a have the meanings given previously. The diameter (two times the radius r) of the focal cylinder allows focused acoustic energy to be directed at both the top side and bottom side of the substrate 88 when it is inserted in the slot 84.

FIG. 6 illustrates the outside of the cleaning tool 40 showing the housing 44 in more detail. In a preferred embodiment, the housing 44 is a six-sided hollow structure having a cuboid shape and comprises a front member 110, a top member 114, a bottom member 116, two side members 120 (one shown), and a back member (not shown), but other designs for the housing 44 can be used. In the preferred embodiment, the housing 44 encloses the resonator 48, the crystal 52, the cleaning chamber 56, the upper fluid source 60, and the lower fluid source 64. The slot 84 is formed in the front member 110 and provides access to the cleaning chamber 56. Preferably, the focal point 90 (fp) is located in the slot 84 and the region around the focal point 90 in the slot 84 is referred to as the cleaning zone.

The RF connection 76 is positioned on the back member. An upper fluid connector 130 and a lower fluid connector (not shown) provide fluid connection to the upper and lower fluid sources 60 and 64, respectively. An RF power source provides power to the crystal 52, preferably in the frequency range of 300 kHz to 5 Mhz. Suitable RF power supplies are commercially available, such as an AB broadband amplifier, but other types such as a DE broadband amplifier can be used. In a preferred embodiment, the RF power supply operates at 925 kHz, but other frequencies such as 300 kHz to 5 MHz can be used. In some applications, the RF power can be switched and phase off-set fired to move or steer the acoustic focal point.

In a preferred embodiment, the housing 44 is comprised of a chemically inert material, such as polytetrafluoroethylene (PTFE) plastic, that is chemically resistant to the cleaning fluid, but other materials could be used for the housing 44. Preferably, the cleaning fluid is a liquid and representative liquid cleaning fluids that can be used include APM (ammonia and hydrogen peroxide mixtures), SPM (sulfuric acid hydrogen peroxide mixture), HCl, hydrofluoric acid (HF) and HF mixtures, HF-nitric acid mixtures, NaClO, and DI (deionized) water. Other cleaning fluids such as ozone containing liquids can be used as well.

In operation, the cleaning tool 40 is used to clean the edge exclusion region of a semiconductor wafer, including the bevel and apex regions as was discussed with respect to FIG. 1. Specifically, the cleaning tool 40 is designed to clean contaminants, such as small particles, from the edge exclusion region 10. Particles probably as small as 20 nm (nanometers) or less can be cleaned with the tool 40, and larger particles such as 5-10-micron particles, or even flake-sized contaminants, can also be cleaned. Generally, the edge exclusion region has a length of approximately three to seven millimeters (3-7 mm).

In a representative cleaning sequence, a circular substrate 88, such as a semiconductor wafer (e.g. a 200- or 300-mm wafer) in some phase of production is caused to rotate such as by using a rotating wafer holder. The transducer 89 is positioned near the edge exclusion region 10, such as by using an actuator to move the tool 40 so that part of the substrate 88, including the edge exclusion region, is inserted in the slot 84. In other embodiments, this could mean moving the wafer so that the edge exclusion region is inserted into the slot 84. The cleaning fluid is caused to flow, such as by pumping cleaning fluid through the upper passageway 68 and a lower passageway 72 and into the cleaning chamber 56. Some of the cleaning fluid flows into the slot 84 and coats at least part of the substrate 88 including the edge exclusion region.

RF power is applied to the crystal 52 which causes acoustic energy to be produced and transmitted through the resonator 48. Generally, the RF power is supplied to the crystal 52 for 15-60 seconds and then stops, but this can be varied depending on the application. The RF power level can also be varied. The shape of the resonator 48 focuses the acoustic energy in a cylindrical region extending along the length S of the crystal in the slot 84 and the acoustic energy is directed to the edge exclusion region by the cleaning fluid which acts both as a cleaning agent and as a coupling agent for the acoustic energy.

The substrate 88 can be moved horizontally (or laterally meaning in the x- or y-directions) in the slot 84 so that different regions of the edge exclusion region are positioned to receive the maximum focused acoustic energy near the focal point fp. This can mean that part of the substrate 88 moves into the cleaning chamber 56 while another region of the substrate is being cleaned in the slot 84. After this period, the cleaning fluid is turned off and a DI (deionized) water rinse is applied to the edge exclusion region for a period such as 5 seconds. After finishing this rinse, power to the tool 40 is turned off and the transducer 89 (i.e. the tool 40) is backed away from the substrate edge, such as by using an actuator. Alternatively, the substrate 88 can be moved out of the slot 84, such as by using an actuator.

Using the cleaning tool 40 in this manner allows the edge exclusion region, including the bevel regions of the wafer to be cleaned in a “non-contact” manner without requiring a brush or other abrasive object to contact the wafer. This process also cleans the edge exclusion region and bevel regions on both sides of the wafer (i.e., on the top and bottom sides) if desired. Use of the cleaning tool 40 can clean particles probably as small as 20 nm (nanometers) or less and larger particles can also be cleaned.

During operation (i.e., during the wafer cleaning process), it may be desirable to keep excess cleaning fluids flowing onto the dies on the wafer or on to other parts of the wafer outside of the edge exclusion zone. This can be accomplished by adjusting parameters such as the spin speed of the wafer, the width of the slot 84, and the flow rate of the cleaning fluid through the upper passageway 68 and a lower passageway 72. This also minimizes the use of cleaning fluids that are sometimes expensive and/or environmentally unfriendly.

In a representative embodiment, the cleaning tool 40 comprises a crystal for generating acoustic energy and a resonator attached to the crystal for propagating (or conducting) at least some of the acoustic energy away from the crystal, with the resonator being shaped to generate focused acoustic energy which is focused at a focal point a distance away from the resonator. The cleaning tool 40 also includes a cleaning zone adjacent to the resonator which is an open space sized to accept a part of a substrate to be cleaned, with the focal point being located in the cleaning zone. For example, the resonator 48 in FIG. 3 is curved (cylindrically shaped) to focus the acoustic energy in the slot 84 which is a distance away from the resonator (i.e. fp is greater than R in FIG. 4), so the slot 84 is the cleaning zone. The slot 84 is an open space adjacent to the resonator that accepts a substrate to be cleaned, and the resonator 48 is designed so that the acoustic energy is focused on the focal point fp which is located in the slot 84 (i.e., in the cleaning zone). Focused acoustic energy means there is greater acoustic power at fp than was emitted from the crystal 89.

When this embodiment is in operation, at least part of a substrate to be cleaned, such as the edge of a semiconductor wafer containing an edge exclusion region, is positioned in the cleaning zone. A volume of liquid cleaning fluid is caused to contact at least the part of the substrate positioned in the cleaning zone and is also in contact with at least part of the resonator. The liquid cleaning fluid transmits (couples) the focused acoustic energy from the resonator to the substrate in the cleaning zone so that the focused acoustic energy impacts at least part of the substrate positioned in the cleaning zone. The combination of the focused acoustic energy and the cleaning fluid cleans the edge exclusion region, such as by dislodging or otherwise removing particles from the edge exclusion region.

In another representative embodiment, the cleaning tool 40 comprises the crystal 52 for generating acoustic energy and the resonator 48 which is attached to the crystal for propagating (or conducting) the acoustic energy away from the crystal. The resonator is shaped to generate focused acoustic energy which is focused at a focal point 90 a distance away from the resonator. A chamber 56 is positioned in contact with the resonator for accepting a volume of liquid cleaning fluid and a cleaning zone is adjacent to the chamber. The cleaning zone (i.e., slot 84) is an open space sized to accept a part of a substrate to be cleaned, with the focal point 90 being located in the cleaning zone, and at least some of the liquid cleaning fluid is able to move from the chamber to the cleaning zone when the volume of liquid cleaning fluid is present in the chamber. When the part of the substrate to be cleaned is positioned in the cleaning zone some of the volume of liquid cleaning fluid can contact the part of the substrate positioned in the cleaning zone (as is shown in FIG. 2) and at least some of the focused acoustic energy can impact at least part of the substrate positioned in the cleaning zone.

Preferably, the transducer 89 is positioned inside a protective housing, such as the housing 44. In a preferred embodiment, the crystal 52 is curved to fit tightly against the curved resonator 48 and comprises a single piece of material. However, in other embodiments different configurations of the crystal can be used, including multiple-piece crystal arrays. In a preferred embodiment, the transducer 89 is designed or shaped to focus at least some of the acoustic energy on a focal zone corresponding to a focal point in the range of approximately 20 to 40 millimeters for the shaped resonator, and more preferably in the range of approximately 25 to 31 millimeters. For example, Table 1 above lists some representative focal points in these ranges and the related text describes the parameters for adjusting the resonator design to achieve these focal points, as well as focal points outside of these ranges. To be clear, it should be noted that adjusting the dimensions of the components in the cleaning tool 40 will change the focal point, including making the focal point larger or smaller than the 20-to-40-millimeter range listed above. For example, a smaller or larger crystal (or other component change) could vary the focal point a lot, so the present invention is not limited to these ranges. The term focused acoustic energy means the acoustic energy is caused to converge onto a focal zone (or focal point) thereby increasing the power of the acoustic energy in the focal zone relative to the power generated at the crystal.

In a representative embodiment, a method for cleaning the edge exclusion region of a semiconductor wafer, including the bevel regions, comprises causing a circular substrate to be rotated, positioning a transducer comprised of a crystal and a shaped resonator near at least a part of the substrate, causing a volume of cleaning fluid to contact at least part of the substrate, generating acoustic energy by applying RF power to the crystal, focusing the acoustic energy by transmitting the acoustic energy generated by the crystal through the shaped resonator to produce focused acoustic energy, and transmitting at least some of the focused acoustic energy into at least some of the volume of cleaning fluid that is in contact with the substrate. In a preferred embodiment, the transducer 89 is designed or shaped to focus at least some of the acoustic energy on a focal zone corresponding to a focal point in the range of approximately 20 to 40 millimeters for the shaped resonator, and more preferably in the range of approximately 25 to 31 millimeters. As was explained previously, changes to the design of the transducer can cause the focal point to be outside of these ranges, so the present invention is not limited to these ranges.

Although the present invention has been described in terms of the presently preferred embodiments, it is to be understood that such disclosure is not to be interpreted as limiting. Various alterations and modifications will no doubt become apparent to those skilled in the art after having read the above disclosure. Accordingly, it is intended that the appended claims be interpreted as covering all alterations and modifications as fall within the true scope of the invention.

We claim:

1. A cleaning tool comprising:
a crystal for generating acoustic energy;
a resonator attached to the crystal for propagating at least some of the acoustic energy away from the crystal, the resonator being shaped to generate focused acoustic energy which is focused at a focal point a distance away from the resonator; and
a cleaning zone adjacent to the resonator which is an open space sized to accept a part of a substrate to be cleaned, with the focal point being located in the cleaning zone.

2. The cleaning tool of claim 1 further comprising:
a housing that surrounds the crystal and the resonator; and
an opening in the housing for allowing at least part of the substrate to be cleaned to be inserted into the cleaning zone.

3. The cleaning tool of claim 2 wherein the part of the substrate to be cleaned comprises an edge of a semiconductor wafer.

4. The cleaning tool of claim 1 wherein the resonator has a focal point in the range of approximately 20 to 40 millimeters.

5. A cleaning tool comprising:
a crystal for generating acoustic energy;
a resonator attached to the crystal for propagating the acoustic energy away from the crystal, the resonator being shaped to generate focused acoustic energy which is focused at a focal point a distance away from the resonator;
a chamber that abuts the resonator for accepting a volume of liquid cleaning fluid when the volume of liquid cleaning fluid is present; and
a cleaning zone adjacent to the chamber which is an open space sized to accept a part of a substrate to be cleaned, with the focal point being located in the cleaning zone, and at least some of the liquid cleaning fluid being able to move from the chamber to the cleaning zone when the volume of liquid cleaning fluid is present;
wherein when the part of the substrate to be cleaned is positioned in the cleaning zone some of the volume of liquid cleaning fluid can contact the part of the substrate positioned in the cleaning zone and at least some of the focused acoustic energy can impact at least part of the substrate positioned in the cleaning zone.

6. The cleaning tool of claim 5 further comprising:
a housing that surrounds the crystal, the resonator, and the chamber; and
an opening in the housing for allowing at least part of the substrate to be cleaned to be inserted into the cleaning zone.

7. The cleaning tool of claim 6 wherein the opening is sized to accept an edge of a semiconductor wafer.

8. The cleaning tool of claim 7 wherein the edge of the semiconductor wafer includes at least part of an edge exclusion region.

9. The cleaning tool of claim 5 wherein the crystal comprises a PZT crystal.

10. The cleaning tool of claim 5 wherein the resonator comprises sapphire.

11. The cleaning tool of claim 5 wherein the resonator has a focal point in the range of approximately 20 to 40 millimeters.

12. The cleaning tool of claim 5 wherein the resonator has a focal point in the range of approximately 25 to 31 millimeters.

13. A method for cleaning a substrate comprising:
causing a circular substrate to be rotated;
positioning a transducer comprised of a crystal and a shaped resonator near at least a part of the substrate;
causing a volume of cleaning fluid to contact at least part of the substrate;
generating acoustic energy by applying power to the crystal;
focusing the acoustic energy by transmitting the acoustic energy generated by the crystal through the shaped resonator to produce focused acoustic energy; and
transmitting at least some of the focused acoustic energy into at least some of the volume of cleaning fluid that is in contact with the substrate.

14. The method of claim 13 further comprising:
after a period of time, causing the cleaning fluid to stop flowing.

15. The method of claim 13 wherein the part of the substrate contacted by the cleaning fluid comprises at least part of the edge exclusion region of a semiconductor wafer.

16. The method of claim 13 wherein the shaped resonator has a focal point in the range of approximately 20 to 40 millimeters.

17. The method of claim 13 wherein the shaped resonator has a focal point in the range of approximately 25 to 31 millimeters.
